(19) United States
(12) Patent Application Publication
(10) Pub. No.: US 2026/0259358 A1
(43) Pub. Date: Sep. 3, 2026

(54) OPTICAL SYSTEM FOR GUIDING ILLUMINATION AND IMAGING LIGHT FROM A LIGHT SOURCE TO AN IMAGE FIELD

(71) Applicant: Carl Zeiss SMT GmbH, Oberkochen (DE)

(72) Inventors: Michael CARL, Aalen (DE); Markus SCHWAB, Aalen (DE); Toralf GRUNER, Aalen (DE)

(21) Appl. No.: 19/654,151

(22) Filed: Apr. 21, 2026

Related U.S. Application Data
(63) Continuation of application No. PCT/EP2024/080451, filed on Oct. 28, 2024.

(30) Foreign Application Priority Data
Oct. 31, 2023 (DE) 10 2023 210 777.5

(51) Int. Cl. G02B 5/28; G02B 7/00; G03F 7/00; H10P 34/00

(52) U.S. Cl. CPC G02B 5/283; G02B 7/006; G03F 7/70308; G03F 7/70316; G03F 7/70575; G03F 7/70825; H10P 34/00

(57) ABSTRACT

An optical system guides illumination and imaging light from a light source to an image field in which a substrate is arrangeable. An optical assembly guides the illumination and imaging light along a beam path between the light source and the image field via at least one field plane and via at least one pupil plane. The light source and/or a chromatic filter arranged downstream of the light source in the beam path are/is embodied such that a wavelength bandwidth between a total wavelength bandwidth and a reduction wavelength bandwidth which is at least 10% smaller than the total wavelength bandwidth is specifiable for the imaging light generated via the light source. The result is an optical system having improved imaging performance for imaging for example objects having structures with different imaging requirements.

### CROSS-REFERENCE TO RELATED APPLICATIONS

The present application is a continuation of, and claims benefit under 35 USC 120 to, international application No. PCT/EP2024/080451, filed Oct. 28, 2024, which claims benefit under 35 USC 119 of German Application No. 10 2023 210 775.5, filed Oct. 31, 2023. The entire disclosure of each of these applications is incorporated by reference herein.

### FIELD

The disclosure relates to an optical system for guiding illumination and imaging light from a light source to an image field. Furthermore, the disclosure relates to a projection exposure apparatus comprising such an optical system, a method for producing a microstructured or nanostructured component with the aid of such a projection exposure apparatus, and a microstructured or nanostructured component produced by such a method.

### BACKGROUND

An optical system is known from EP 1 959 302 B1 and WO 2019/145 126 A1. The use of filters in lithographic exposure apparatuses is known from WO 2012/160 928 A1, U.S. Pat. No. 8,760,628 B and KR 20140051706 A. U.S. Pat. No. 4,853,756 discloses a projection exposure apparatus. US 2001/0028669 A1 discloses a laser which can be used as a light source in a projection exposure apparatus. DE 10 2011 080 919 A1 discloses a microlithographic projection exposure apparatus and a method for operating same.

### SUMMARY

The present disclosure seeks to develop an optical system with improved imaging performance for imaging for example objects having structures with different imaging requirements.

According to the disclosure, it has been recognized that firstly a defocus tolerance and secondly a minimum contrast requirement can be adapted to respective object structure types by way of a variation of a wavelength bandwidth of the illumination and imaging light used to image a structure on the object into the image field. When imaging the object with the total wavelength bandwidth, the result can be a high defocus tolerance, and so even object structures with a relatively large extent perpendicular to the field can be imaged. When imaging with the reduced reduction wavelength bandwidth, the result can be a higher minimum imaging contrast, and so it is thereby possible to image even object structures having higher contrast requirements, such as finer object structures. The total wavelength bandwidth can be 2.5 nm at an average used wavelength of 365 nm. At an average used wavelength of 13.5 nm, the total wavelength bandwidth can be 0.6 nm. For example, contact holes with a relatively large extent perpendicular to the field can be imaged well using the total wavelength bandwidth, wherein finer structures on the same reticle can also be imaged at the same time, then with the aid of the reduction wavelength bandwidth.

A light source can be part of the optical system, but this is not mandatory insofar as the chromatic filter belongs to the optical system, and so the optical system can also be provided separately as an assembly that is adaptable to an external light source.

The chromatic filter or the light source is arranged in the region of a field plane of the optical system. This can help enable portionwise influencing of field portions via a corresponding design of the chromatic filter or of the light source with a corresponding (field-) portionwise spectral characteristic. Specific field regions can thus be targetedly influenced spectrally differently than other field regions, such that an adapted spectral characteristic of the illumination and/or imaging light can then be specified in each case by way of the chromatic filter or by way of the light source in a manner adapted to structure portions on the object to be imaged. By way of example, specific object portions of the object to be imaged can then be illuminated targetedly with a wavelength bandwidth adapted for example to the object structure portions to be imaged that are present there.

In a first aspect, the disclosure provides an optical system for guiding illumination and imaging light from a light source to an image field in which a substrate is arrangeable. The optical system serves for illuminating an object field, in which an object to be imaged is arrangeable, and/or for imaging the object field into the image field. The optical system comprises an optical assembly for guiding the illumination and imaging light along a beam path between the light source and the image field via at least one field plane and via at least one pupil plane. The light source and/or a chromatic filter arranged downstream of the light source in the beam path are/is embodied such that a wavelength bandwidth between a total wavelength bandwidth and a reduction wavelength bandwidth which is at least 10% smaller than the total wavelength bandwidth is specifiable for the imaging light generated by the light source. The chromatic filter or the light source is arranged in the region of a field plane of the optical system.

In embodiments, the chromatic filter reduces the total wavelength bandwidth of the illumination and imaging light guided via the beam path upstream of the chromatic filter to the reduction wavelength bandwidth, and/or the light source is embodied as a tunable light source. In such embodiments, the light source can be embodied as a tunable light source and can then be part of the optical system. The light source can have at least one laser diode with a temperature-dependent emission wavelength.

In embodiments, the chromatic filter is arranged in an imaging optical unit of the optical system for imaging the object field into the image field. Such embodiments can enable a good adaptation of the chromatic filter to imaging conditions of the imaging optical unit. Alternatively, the chromatic filter can also be arranged in an illumination optical unit of the optical system for illuminating the object field.

In embodiments, the light source is embodied as an array of wavelength-tunable individual light sources. Such embodiments can make it possible to adapt a wavelength bandwidth in a spatially resolved manner to imaging requirements of the optical system. The light source can have a plurality of corresponding individual light sources between a minimum number of, for example, 3 individual light sources and a maximum number of, for example, 1,000 individual light sources, such as individual light source numbers in the range of between 10 and 100.

In embodiments, the chromatic filter and/or the light source are/is arranged overall in the region of a pupil plane of the optical system. Such embodiments can enable a chromatic adaptation of a wavelength bandwidth of the illumination and imaging light depending on the object illumination angle.

This is possible for example in the case of In embodiments, the chromatic filter having a chromatic filter effect only in a portion of a pupil. An outer ring portion of the chromatic filter can then transmit the illumination and imaging light with the reduction wavelength bandwidth, such that denser lines, the orders of diffraction of which pass through this outer ring portion, are imaged with high contrast. By contrast, coarser structures are imaged with an increased depth of field since the depth of field is proportional to 1/NA² and the blocked light has a reduced NA, where NA denotes the image-side numerical aperture of the projection optical unit. Alternatively, such portionwise influencing of a wavelength bandwidth can also be realized by way of an arrangement of the array light source in the pupil plane and corresponding individual control of the individual light sources.

In embodiments, the chromatic filter has a chromatic filter effect only in a portion of the field. In such embodiments, the chromatic filter can be adapted to a distribution of object structures on the object to be imaged. Field portions of the chromatic filter can then be specified with a corresponding wavelength bandwidth filter effect. Alternatively, here as well a corresponding field-dependent effect of the wavelength bandwidth can be settable by way of an array light source in a field plane.

In embodiments, insofar as the chromatic filter has a chromatic filter effect only in a portion of an entire cross section of the beam path of the illumination and imaging light, a remaining portion of the beam path is covered by a compensation filter portion. Such embodiments can afford the possibility of ensuring a total transmission of the chromatic filter over an entire cross section of the beam path even if the chromatic filter has a chromatic effect only in a portion of the cross section of the beam path. The compensation filter portion can be part of a filter unit that also includes the chromatic filter. Alternatively, the chromatic filter, firstly, and the compensation filter portion, secondly, can be two components separate from one another.

The compensation filter can be embodied as a neutral density filter. Alternatively or additionally, the compensation filter can also be embodied as a filter having a different chromatic effect. The compensation filter can have a spectral filter characteristic that deviates from the chromatic filter.

An embodiment of the chromatic filter as an interference filter has proved worthwhile in practice.

An embodiment of the chromatic filter as a high-pass filter ensures that within the reduction wavelength bandwidth advantageously smaller wavelengths pertaining to the total wavelength bandwidth are available for imaging and a correspondingly high resolution can thus be made possible. Alternatively, the chromatic filter can also be embodied as a low-pass filter or else as a bandpass filter.

In embodiments, the optical system includes a filter interchange holder, in which the chromatic filter is held such that it is displaceable between a used position, in which the chromatic filter is arranged in the beam path, and a neutral position, in which the chromatic filter is arranged outside the beam path. In such embodiments, the filter interchange can enable the chromatic filter to be switched on as desired. Such a filter interchange holder can also be used for changing between a plurality of different chromatic filters. By this means, it is possible to realize a sequential exposure of one and the same object using different chromatic filters, or else it is possible to adapt the chromatic filter to different object structure distributions.

In a second aspect, the disclosure provides an optical system for guiding illumination and imaging light from a light source to an image field, in which a substrate is arrangeable. The optical system serves for illuminating an object field, in which an object to be imaged is arrangeable, and/or for imaging the object field into the image field. The optical system comprises an optical assembly for guiding the illumination and imaging light along a beam path between the light source and the image field via at least one field plane and via at least one pupil plane. The light source and/or a chromatic filter arranged downstream of the light source in the beam path are/is embodied such that a wavelength bandwidth between a total wavelength bandwidth and a reduction wavelength bandwidth which is at least 10% smaller than the total wavelength bandwidth is specifiable for the imaging light generated by the light source. The chromatic filter is arranged in an imaging optical unit of the optical system for imaging the object field into the image field. Optionally, the chromatic filter or the light source need not necessarily be arranged in the region of a field plane of the optical system.

In a third aspect, the disclosure provides an optical system for guiding illumination and imaging light from a light source to an image field, in which a substrate is arrangeable. The optical system serves for illuminating an object field, in which an object to be imaged is arrangeable, and/or for imaging the object field into the image field. The optical system comprises an optical assembly for guiding the illumination and imaging light along a beam path between the light source and the image field via at least one field plane and via at least one pupil plane. The light source and/or a chromatic filter arranged downstream of the light source in the beam path are/is embodied such that a wavelength bandwidth between a total wavelength bandwidth and a reduction wavelength bandwidth which is at least 10% smaller than the total wavelength bandwidth is specifiable for the imaging light generated by the light source. The chromatic filter and/or the light source are/is arranged overall in the region of a pupil plane of the optical system. Optionally, the chromatic filter or the light source need not necessarily be arranged in the region of a field plane of the optical system.

In a fourth aspect, the disclosure provides a projection exposure apparatus comprising an optical system according to the disclosure, a reticle holder for holding a reticle in an object plane, a projection lens for imaging the object field into an image field in an image plane, and comprising a wafer holder for holding a wafer in the image plane.

In a fifth aspect, the disclosure provides a method for producing a microstructured or nanostructured component, comprising the following method steps: providing a projection exposure apparatus according to the disclosure, which comprises a light source correspondingly adapted to the object to be formed and/or a chromatic filter correspondingly adapted to the object to be imaged; providing the object and a wafer; imaging a structure on the object on the wafer using the projection exposure apparatus; and processing the exposed wafer for forming the microstructured component.

In a sixth aspect, the disclosure provides a component, produced according to a method according to the disclosure.

Optical systems according to the second and third aspects can be combined with the other features discussed above in connection with the optical system as claimed according to the first aspect.

The illumination system can have a DUV (deep ultraviolet) light source (wavelengths for example in the range of between 150 nm and 380 nm) or else an EUV light source (extreme ultraviolet, wavelengths of between 5 nm and 100 nm).

For example, a microstructured or nanostructured component, especially a semiconductor chip, for example a memory chip, can be produced using the projection exposure apparatus.

### BRIEF DESCRIPTION OF THE DRAWINGS

Exemplary embodiments of the disclosure are explained in more detail below with reference to the drawing, in which:

FIG. 1 shows a schematic overview of a microlithographic projection exposure apparatus in a meridional section, having an illumination optical unit for illuminating an object field and a projection lens for imaging the object field into an image field;

FIG. 2 shows, in a meridional section, one embodiment of a projection lens of the projection exposure apparatus according to FIG. 1;

FIG. 3 shows, in a diagram, a dependence of an imaging contrast on a defocus value during imaging by the projection lens of the projection exposure apparatus, illustrated for two wavelength bandwidths of illumination and imaging light, specified by way of a light source and/or by way of a chromatic filter of the projection exposure apparatus, the chromatic filter being arranged downstream of the light source in the beam path of the illumination or imaging light;

FIG. 4 shows a process window representation of a dose error depending on a defocus value and depending on whether or not the chromatic filter is used in the beam path of the illumination or imaging light;

FIG. 5 shows a plan view of the chromatic filter for arrangement in a pupil plane of the optical system;

FIG. 6 shows, in a diagram, a dependence of a transmission of an outer filter portion of the filter according to FIG. 5 on a wavelength;

FIG. 7 shows a plan view of an object in the form of a reticle that is arrangeable in the object field of the projection exposure apparatus and is to be imaged during projection lithography;

FIG. 8 shows, in a diagram similar to FIG. 6, a further embodiment of a transmission profile of a variant and/or of another portion of the chromatic filter;

FIG. 9 shows one embodiment of a lens of the illumination optical unit for imaging an intermediate field plane into the object field; and

FIG. 10 shows, in a plan view, one embodiment of a light source of the projection exposure apparatus, embodied as a hexagonal array of wavelength-tunable individual light sources.

### DETAILED DESCRIPTION

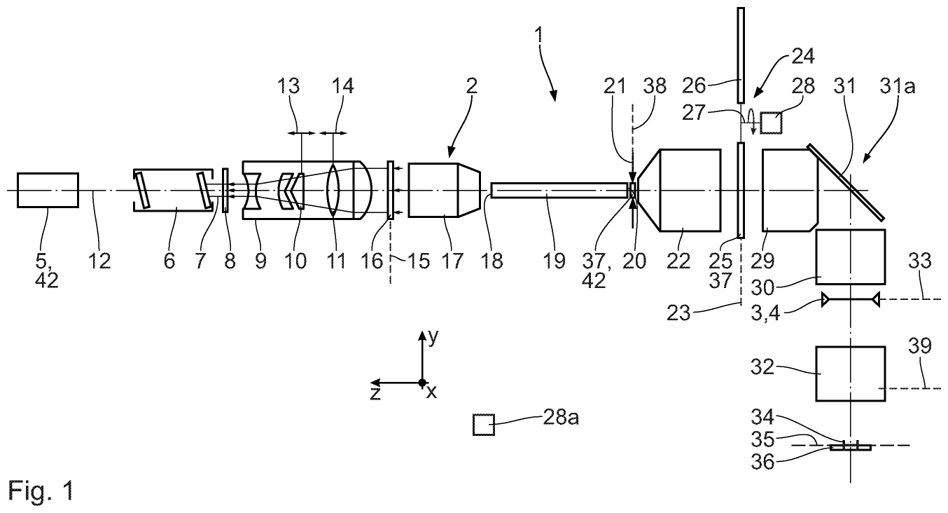

In order to elucidate positional relationships, a Cartesian xyz-coordinate system is specified in the drawing. In FIG. 1, the x-axis runs perpendicular to the plane of the drawing out of the latter. The y-axis runs upward in FIG. 1. The z-axis runs toward the left in FIG. 1.

A microlithographic projection exposure apparatus 1 has an illumination system comprising an illumination optical unit 2 for illuminating a defined illumination or object field 3 at the location of an object or a reticle 4, which represents a template to be projected for the production of microstructured or microelectronic semiconductor components. The reticle 4 is held by a reticle holder, not illustrated here.

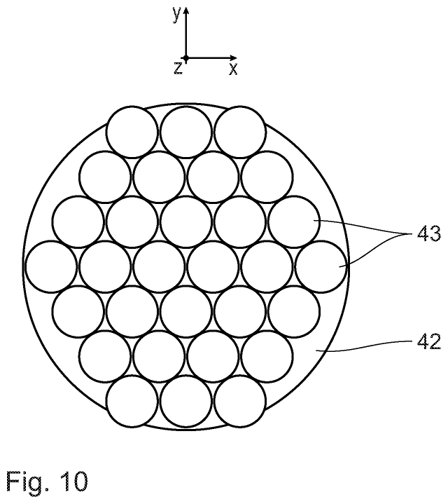

A laser in the deep ultraviolet (DUV) is used as a light source 5 for illumination light of the illumination system. This can be an ArF excimer laser. Other DUV sources are also possible. A variant of the light source 5 will also be explained below with reference to FIG. 10.

A beam expander 6, for example a mirror arrangement known from DE-A 41 24 311, is used to reduce coherence and generate an expanded, collimated, rectangular cross section of a beam of the illumination light 7.

A first diffractive optical grid element (DOE) 8 is arranged in an object plane of a condenser 9. This DOE 8 is also referred to hereinafter as intensity specification element. The condenser 9 comprises an axicon pair 10 and a lens element 11 with a positive focal length. The spacing between the axicon elements of the axicon pair 10 and the position of the lens element 11 are adjustable along an optical axis 12 of the illumination optical unit 2, as indicated by double-headed arrows 13, 14 in FIG. 1. Therefore, the condenser 9 constitutes a zoom optical unit.

A further diffractive and/or refractive optical grid element (ROE) 16 is arranged in an exit pupil plane 15 of the condenser 9. Insofar as the grid element 16 has a diffractive embodiment, it can be embodied as a computer-generated hologram (CGH), for example. As an alternative or in addition to the configuration as a diffractive optical element, the ROE 16 can have a refractive embodiment, for example as a refractive optical grid element, such as a microlens array. Although a diffractive embodiment is also possible, the grid element 16 is referred to hereinafter as ROE.

Using the first DOE 8, a defined intensity distribution in the pupil plane 15 is set at the location of the ROE 16. This generates a specified so-called illumination setting, i.e. a defined distribution of illumination angles over the object field 3. Therefore, the first DOE 8 constitutes an illumination angle specification element for specifying an illumination angle distribution over the object field 3.

An input coupling optical unit 17 disposed downstream of the ROE 16 transmits the illumination light to an end-side entrance surface 18 of a transparent optical rod in the form of a glass rod 19.

The optical rod 19 has a rectangular cross section. This rod cross section is generally polygonal and can for example also be square or hexagonal.

The rod 19 mixes and homogenizes the illumination light by multiple internal reflection at the lateral walls of the rod 19. An intermediate field plane in which a reticle masking system (REMA) 21, an adjustable field stop, is arranged is situated directly on an end-side exit surface 20 of the rod 19 situated opposite the entrance surface 18.

The ROE 16 is used, inter alia, to adapt the cross-sectional shape of the illumination beam 7 to the rectangular shape of the entrance surface 18 of the rod 19.

The ROE 16 is also referred to hereinafter as optical rod illumination specification element. The ROE 16 serves to specify an illumination of the entrance surface 18 of the rod 19 by way of the illumination light 7. The illumination of the entrance surface 18 is specified in such a way that this specifies a distribution of the illumination intensity and, at the same time, the illumination angle distribution over the entrance surface 18. The specified illumination intensity distribution over the entrance surface 18 deviates from a homogeneous distribution, as will be explained in even greater detail below.

The DOE 8, i.e. the intensity specification element, is used to specify an illumination intensity distribution on the ROE 16, i.e. on the optical rod illumination specification element.

A condenser 22 is disposed downstream of the REMA 21. A stop interchange holder 24 with a plurality of stops or filters can be arranged in an exit pupil plane 23 of the condenser 22, two stops 25, 26 of the plurality of stops or filters being illustrated in FIG. 1. The stop interchange holder 24 carries the various stops in the style of a stop carousel. For stop interchange purposes, the carousel is driven about a drive shaft 27 of a drive motor 28, which is signal-connected to a central control device 28a of the projection exposure apparatus 1. The stops of the stop interchange holder 24 are subdivided into an even number of separate stop portions. The stop portions can be stops that completely block the illumination light, neutral density filters that attenuate the illumination light by a specified percentage, or polarization filters that linearly polarize the illumination light.

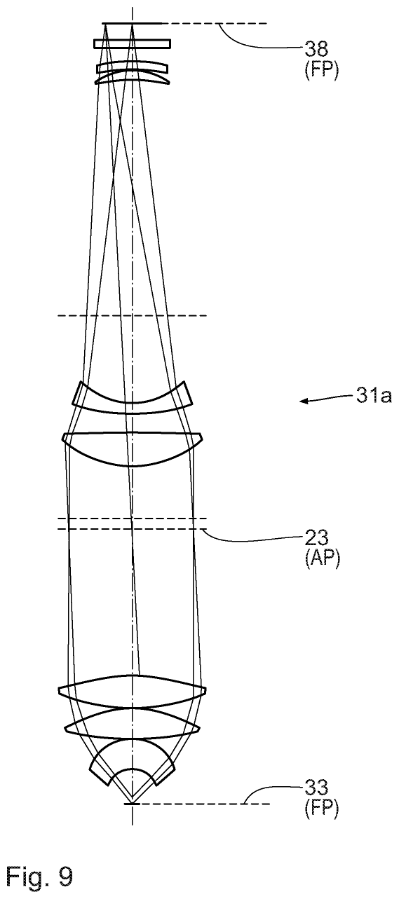

A further condenser with lens-element groups 29, 30 is disposed downstream of the pupil plane 23 disposed downstream of the rod 19. A 90° deflection mirror 31 for the illumination light is arranged between the two lens-element groups 29, 30. The condenser 22 and the further condenser with the two lens-element groups 29, 30 form a lens 31a, which images the intermediate field plane of the REMA 21 onto the reticle 4. The pupil plane 23 constitutes an internal pupil plane of this lens 31a. One embodiment of the lens 31a is illustrated in a meridional section in FIG. 9 and is known in principle from U.S. Pat. No. 6,295,122 B1.

A projection lens 32 images the object field 3 situated in an object plane 33 into an image field 34 in an image plane 35. The image field 34 is part of the surface of a wafer 36 to be exposed, which is provided with a coating that is sensitive to the illumination light. The wafer 36 is held by a wafer holder, not illustrated here. During projection exposure, the reticle 4 and the wafer 36 are scanned synchronously with one another. An intermittent displacement of the holders of the reticle 4 and of the wafer 36, so-called stepper operation, is also possible.

With the exception of the deflection mirror 31, the various beam-guiding or beam-shaping components of the projection exposure apparatus 1 are indicated as refractive components. They can equally also be catadioptric or reflective components. The illumination optical unit 2 including the REMA lens 31a, firstly, and the projection lens 32, secondly, form an optical system of the projection exposure apparatus 1.

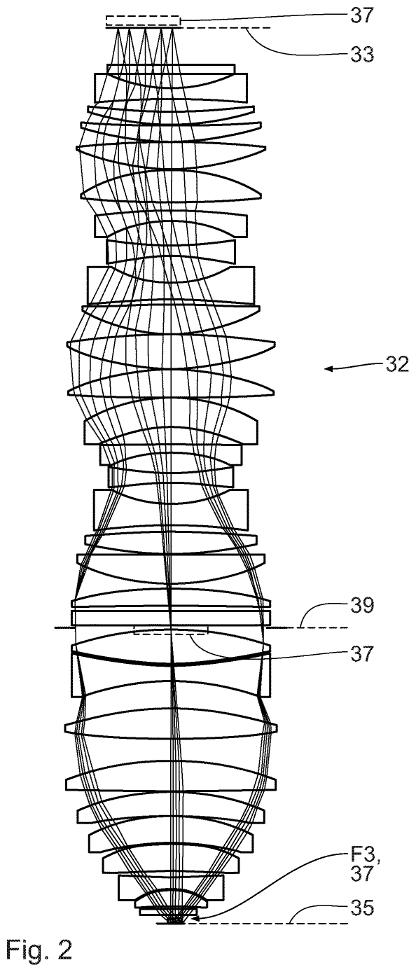

FIG. 2 shows one embodiment of the projection lens 32, once again in a meridional section. Such a projection lens is known in principle from U.S. Pat. No. 8,970,964 B2.

In one embodiment of the projection exposure apparatus 1, a chromatic filter 37 is arranged downstream of the light source 5 in the beam path of the illumination and imaging light 7. Exemplary arrangement planes for the chromatic filter are a field plane 38 of the field stop 21, the exit pupil plane 23 of the lens 31a, an arrangement plane adjacent to the object plane 33, an exit pupil plane 39 of the projection lens 32 or else an arrangement plane which is adjacent to the image plane 35 and still situated upstream thereof in the beam path.

By way of example, for an arrangement within the illumination optical unit, arrangement positions of the chromatic filter 37 at the location of the field stop 21 and at the location of the stop 25 are illustrated in FIG. 1. Further arrangement variants for the chromatic filter 37 are illustrated in FIG. 2 near the object plane 33, in the exit pupil plane 39 and near the image plane 35 on the basis of the example of an exit surface of the component F3 of the projection optical unit 32. Depending on the application that will also be described below, the chromatic filter 37 can be arranged in the region of an accessible field plane and/or in the region of an accessible pupil plane of the optical system in the beam path of the illumination and imaging light 7 upstream of the image field 34.

The chromatic filter 37 is embodied in such a way that a wavelength bandwidth which lies between a total wavelength bandwidth of the light source 5 and a reduction wavelength bandwidth is specifiable for the imaging light 7 in the beam path upstream of the image field 34. The reduction wavelength bandwidth is at least 10% smaller than the total wavelength bandwidth.

In one embodiment of the projection exposure apparatus 1, the light source 5 is embodied as a mercury vapor lamp, wherein the i-line of the emission spectrum is used as the illumination and imaging light 7. A total wavelength bandwidth emitted by the light source 5 as used light can be 2.5 nm around an average used wavelength of 365 nm. The chromatic filter 37 acts as a high-pass filter and/or as a low-pass filter and/or as a bandpass filter in such a way that it reduces this total wavelength bandwidth by at least 10% to the reduction wavelength bandwidth at least over a portion of an entire beam cross section of the illumination and imaging light 7 in the beam path of the optical system.

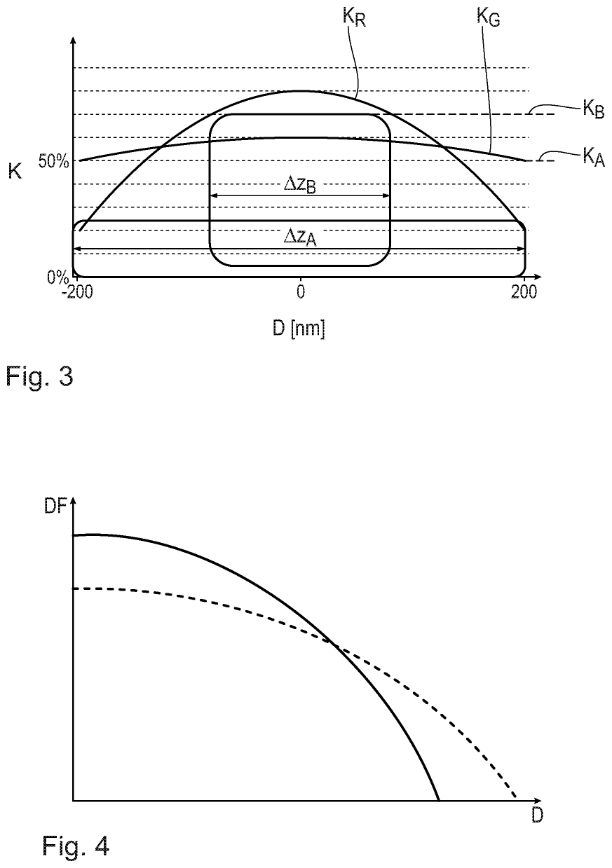

FIG. 3 elucidates the effect of this bandwidth reduction by the chromatic filter 37 on an imaging contrast K when imaging structures of the reticle 4 onto the wafer 36.

The ordinate of FIG. 3 represents the imaging contrast K of this imaging, plotted in percent. K here denotes the energetic Michelson contrast in the image of a given local object structure to be imaged, given by the ratio

$$K := \frac{{I}_{m ax} - {I}_{m i n}}{{I}_{m ax} + {I}_{m i n}} ,$$

where Iₘₐₓ and Iₘᵢₙ denote a maximum and a minimum illumination dose in the image field portion of the image of the local object structure over an illumination process. In this case, as a function of the field point, the illumination dose is proportional to the intensity averaged over the wavelength spectrum and the exposure time during the illumination of the local object structure to be imaged with the illumination light 9.

A defocus value D in nm centered around a defocus of 0 is plotted on the abscissa. The defocus value specifies how a focus of an imaging beam path of the projection lens 32 is spaced apart from the image plane 35 proceeding from an object point along the beam path. In the case of a defocus of 0, the focus of this imaging beam path lies exactly in the image plane 35. The defocus values are plotted on the abscissa of FIG. 3 between values of −200 nm and 200 nm.

Alternatively, a total wavelength bandwidth when using an EUV projection exposure apparatus can also be in the range of between 13.2 nm and 13.8 nm, i.e. can have a bandwidth of 0.6 nm. In this case, this total wavelength bandwidth of 0.6 nm is reduced by at least 10% to a value of at most 0.54 nm by way of the chromatic filter 37.

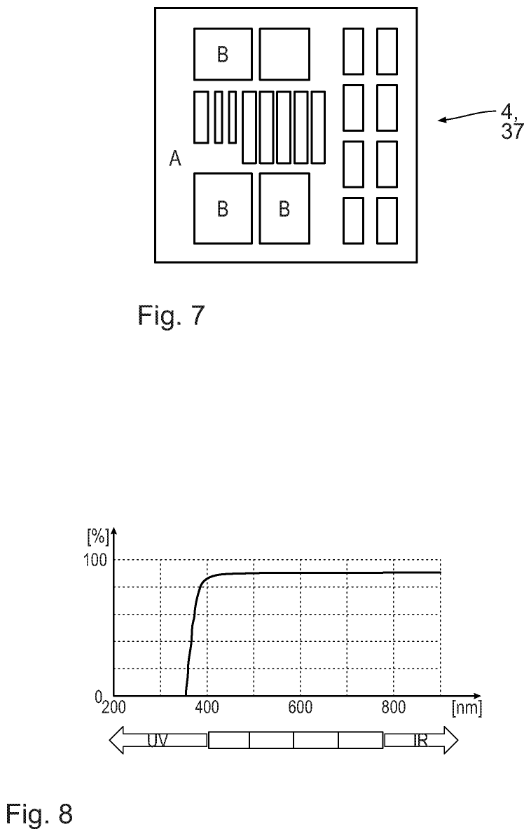

FIG. 7 shows, by way of example, a reticle 4 to be imaged via the projection exposure apparatus 1. A plurality of structure portions A, B lie on the reticle 4. FIG. 7 highlights one structure portion A, on which coarser structures, for example contact holes, are arranged. In comparison therewith, dense structures, for example line structures of a small structure period, lie in the structure region B.

FIG. 3 elucidates contrast requirements firstly for the coarser structures A with a minimum contrast value KA of 50% and secondly for the finer structures B with a minimum contrast value KB of 70%.

The minimum contrast value KA for the coarser structures A is achieved when the coarser structures A are exposed to the imaging light 7 having the total wavelength bandwidth. A contrast curve KG showing the contrast value K in the case of illumination with the total wavelength bandwidth as a function of the defocus value D lies above the minimum contrast value KA over all of the defocus values illustrated. Thus, the full used light spectrum of the imaging light 7 is used, which leads to a tolerable depth of field of the imaging by the P projection lens 32 over the entire defocus range of between −200 nm and +200 nm. The coarse structures A, i.e. for example contact holes, can thus be imaged with sufficient contrast even if they have an extent of up to 400 nm perpendicular to the image field 34.

The higher minimum contrast of 70% is not achieved at all when the object 4 is exposed to the total wavelength bandwidth (contrast curve KG). A maximum contrast value that can be achieved for defocus 0 with an exposure with the total wavelength bandwidth is approximately 60%.

When the object 4 is exposed to the imaging light 7 with the reduction wavelength bandwidth, a resulting contrast curve KR over the defocus has an imaging contrast maximum of 80% for a defocus of 0 and lies above the minimum contrast value KB for the finer structures B between defocus values of −80 nm and 80 nm. A defocus of between −80 nm and 80 nm can thus be tolerated when the finer structures of the object 4 are exposed to the imaging light 7 with the reduction wavelength bandwidth, such that the dense structures are formed with sufficient contrast in the case of an extent perpendicular to the image field of up to 160 nm.

An exposure with the total wavelength bandwidth thus enables imaging of the coarser structures A with a high defocus tolerance in conjunction with a sufficient minimum contrast value KA, whereas the exposure of denser structures with the reduction wavelength bandwidth leads to imaging with an increased minimum contrast value KB while accepting a lower defocus tolerance.

In FIG. 3, the defocus tolerance for the coarse structures A is illustrated at Δz_{A} and the defocus tolerance for the fine structures B is illustrated at Δz_{B}.

Alternatively, for a given object structure to be imaged, it is possible to describe an imaging effect of the chromatic filter 37 in a projection exposure apparatus 1 using the process window thereof, defined as a set of tolerable error tuples (i.e. ones that do not adversely affect the function of the projection system) consisting of relative CD error, dose error and defocus. FIG. 4 schematically shows an edge of such a process window for a dense line structure in the case of a fixed maximum CD error, firstly with (solid line) and secondly without (dashed line) a chromatic filter 37. The illustration shows a dose error DF as a function of a defocus value D.

By way of example, the chromatic filter 37 can act in the optical used pupil region of the pupil plane 23, 39 for illuminating the given object structure to be imaged, while the complement of this used pupil region has other chromatic filters serving for modifying the process windows of other structures. Such filtering can likewise be carried out near a field plane.

In the example in FIG. 4, an increased dose error tolerance results for smaller defocus values D when the chromatic filter 37 is used.

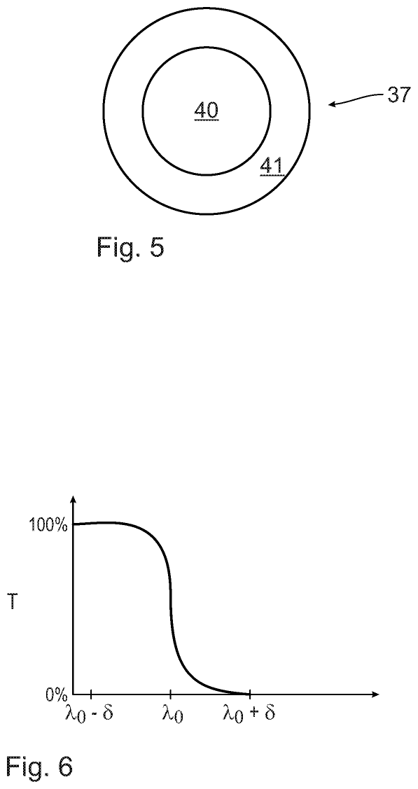

FIG. 5 shows, in a plan view, one embodiment of the chromatic filter 37 for an arrangement in one of the pupil planes 23, 39 of the optical system of the projection exposure apparatus 1. The chromatic filter 37 is subdivided into a core portion 40 and into a ring portion 41 surrounding the latter on the outside.

In the core portion 40, the chromatic filter 37 is embodied for the transmission T of the total wavelength bandwidth of the illumination and imaging light 7. In the outer ring portion 41, the chromatic filter 37 is embodied for the transmission of the reduction wavelength bandwidth.

FIG. 6 shows a variant of a wavelength-dependent transmission T of the chromatic filter 37 in the ring portion 41. At wavelengths λ which are greater than a cut-off wavelength λ₀, the transmission T of the chromatic filter 37 in the ring portion 41 rapidly decreases to values of the order of 0%. At wavelengths below the cut-off wavelength 20, the transmission of the chromatic filter 37 in the ring portion 41 rapidly increases to values of the order of 100%. An edge steepness of this transmission curve according to FIG. 6 can be described by way of a wavelength increment δ, within which there is a drop in transmission from, for example, 99% (λ₀-δ) to 1% (λ₀+δ). δ can be in the range of between 0.01 nm and 1 nm, for example in the range of between 0.05 nm and 0.5 nm.

The cut-off wavelength λ₀ is chosen such that the total wavelength bandwidth of the illumination and imaging light 7 originally incident on the chromatic filter 37 is reduced to the reduction wavelength bandwidth. A total wavelength bandwidth of, for example, 2.5 nm can then be reduced for example to a value of 2.25 nm, of 2 nm, of 1.8 nm, of 1.5 nm.

FIG. 6 describes the chromatic filter 37 in the outer ring portion 41 as a low-pass filter, in which, therefore, a low-energy portion of the illumination and imaging light 7 with smaller wavelengths is transmitted and a high-energy portion of the illumination and imaging light 7 with larger wavelengths is blocked. Alternatively or additionally, the chromatic filter 37 can be embodied at least in portions as a high-pass filter or else as a bandpass filter.

In order to ensure homogeneity of an illumination intensity during imaging via the projection exposure apparatus 1, a neutral portion of the chromatic filter 37, for example the core portion 40 in the embodiment according to FIG. 5, can be embodied with a neutral filter effect, such as a neutral density filter. This neutral filter effect can be such that, in a surface-normalized manner, the illumination and imaging light 7 passing through the chromatic filter 37 is attenuated in the neutral portion in the same way as when passing through the wavelength-selective filter portion, for example through the ring portion 41 of the embodiment according to FIG. 5. By way of such a neutral filter effect, it is also possible to bring about an additional compensatory effect via the chromatic filter 37 in order, for example, to compensate for illumination inhomogeneity effects which occur elsewhere within the illumination system or the optical system of the projection exposure apparatus 1. The neutral portion or core portion 40 of the chromatic filter 37 is also referred to as compensation filter portion.

The chromatic filter 37 according to FIG. 5 can be used for the projection exposure of a reticle 4 according to FIG. 7 as follows:

For the projection exposure of the coarse structures A, an illumination setting is chosen in which the illumination and imaging light 7 passes exclusively through the core portion 40 of the chromatic filter 37, i.e. an illumination setting with smaller illumination angles. The coarse structures A can then be imaged with the high defocus tolerance Δz_{A}.

For the projection exposure of the fine structures B of the reticle 4 according to FIG. 7, an illumination setting is chosen in which the illumination and imaging light 7 impinges on the ring portion 41 of the chromatic filter 37, i.e. an illumination setting with large illumination angles. In this case, the fine structures B are imaged with high minimum contrast within the defocus tolerance Δz_{B}.

The illumination setting variants explained above are set sequentially, but can in principle also be set in parallel.

FIG. 8 shows a further embodiment of a wavelength-dependent transmission profile of at least one surface portion of one embodiment of the chromatic filter 37. In the transmission profile according to FIG. 8, the corresponding chromatic filter 37 or its filter portion is embodied as a high-pass filter. In this case, a cut-off wavelength is in the region of a maximum of a usable total wavelength bandwidth of the i-line at 365 nm.

The chromatic filter 37 can be embodied as an interference filter.

In a variant of the projection exposure apparatus 1, a reduction of a possible total wavelength bandwidth of the light source is realized by way of corresponding control of the light source itself.

FIG. 10 shows, by way of example, a light source 42 of this type in a plan view. This light source is embodied as an array of individual light sources 43 which are tunable independently of one another in terms of their wavelength. This array is illustrated by way of example as a hexagonal array in FIG. 10. Some other dense packing of the individual light sources 43, for example in the form of a line grid array, is also possible.

Each of the individual light sources 43 is embodied as a thermally tunable laser diode. Such laser diodes can have for example a central wavelength close to the i-line, for example between 375 and 410 nm, as described in more detail in https://www.ushio.eu/de/produkt/uv-laserdioden-375 nm-410 nm/.

A thermal tunability of the respective individual light sources 43 can be 0.25 to 0.3 nm/K, for example.

The individual light sources 43 can be laser diodes arranged directly there or else exit surfaces of optical fibers which guide the illumination and imaging light 7 from the laser diodes, then arranged at a distance, to these exit surfaces.

In the case of an alternative arrangement of the chromatic filter 37 in one of the field planes 38, 33, 35 of the optical system, a portionwise filter effect can also be adapted exactly to the position of the coarse structures A and the fine structures B of the respective reticle 4. In a plan view, such a chromatic filter 37 is then subdivided into portions with different filter effects, which are arranged like the reticle portions in the plan view of the reticle 4 according to FIG. 7.

At the locations of the coarse structures A, there is then for example a neutral or compensation filter effect corresponding to the filter effect of the core portion 40 of the embodiment of the chromatic filter 37 according to FIG. 5.

At the locations of the fine structures B, there is correspondingly a bandwidth-reducing filter effect of the chromatic filter 37, as explained above in connection with the ring portion 41 of the embodiment according to FIG. 5.

In the case of this field plane arrangement of the chromatic filter 37, then correspondingly the coarse structures A are imaged with the total wavelength bandwidth and the fine structures B are imaged with the reduction wavelength bandwidth, which leads to the high defocus tolerance for the coarse structures A and to the high minimum contrast for the fine structures B.

Depending on the arrangement of this light source 42 in a pupil plane or in a field plane of the optical system, a corresponding effect increasing the imaging performance of the projection exposure apparatus 1 can be achieved via the array light source 42, as explained above in connection with the arrangements of the chromatic filter 37 in a pupil plane or a field plane of the optical system.

In the case of an arrangement of the array light source 42 in a pupil plane of the optical system, for example, an outer ring of the individual light sources 43 can be controlled such that the reduction wavelength bandwidth results there. Those individual light sources 43 which are arranged in an inner portion of the array of the array light source 42 can in turn be controlled such that the total wavelength bandwidth is emitted.

In the case of an arrangement of the array light source 42 in a field plane of the optical system, for example, at the location of the fine structures B the individual light sources 43 can be controlled in such a way that the reduction wavelength bandwidth results there. At the location of the coarse structures A, the individual light sources 43 arranged there can in turn be controlled such that the total wavelength bandwidth is emitted.

Exemplary arrangement possibilities for the light source 42 in the optical system of the projection exposure apparatus 1 are illustrated in FIG. 1 at the location of the light source 5, corresponding to a pupil plane of the optical system, or at the location of the REMA field stop 21, corresponding to a field plane of the optical system. Insofar as the light source 42 is arranged at the location of the REMA field stop 21, it is possible of course to omit upstream components in the beam path of the optical system according to FIG. 1.

Depending on the embodiment or depending on the desired operating properties of the projection exposure apparatus 1, it is also possible to provide a plurality of different chromatic filters in the style of the chromatic filters 37 explained above, in order to carry out an adaptation to the respective reticle 4 to be imaged. When arranged in a pupil plane of the optical system, these chromatic filters 37 can differ for example in a number and position of the ring portions around the core portion. When the chromatic filter 37 is arranged in a field plane of the optical system, these different chromatic filters 37 can differ in the arrangement of the filter portions for generating the reduction wavelength bandwidth.

Such different filters can in turn be introduced into the beam path of the illumination and imaging light 7 using a filter interchange holder into the beam path of the illumination and imaging light 7, which can correspond in terms of its construction to the stop interchange holder 24 explained above in association with FIG. 5.

During the microlithographic production of a microstructured or nanostructured component, firstly the chromatic filter 37 and/or the light source 42 are/is selected or tuned depending on the reticle 4 to be imaged. The wafer 36 is coated at least in portions with a light-sensitive layer. Then, a structure on the reticle 4 is projected onto the wafer 36 using the projection exposure apparatus 1. After that, the exposed wafer 36 is processed for forming the microstructured component. A correspondingly microstructured or nanostructured semiconductor component, for example a microchip, such as a memory chip, can be produced.

What is claimed is:

1. An optical system configured to guide illumination and imaging light from a light source to an image field in which a substrate is arrangeable, the optical system configured to illuminate an object field in which an object is arrangeable and/or to image the object field into the image field, the optical system comprising:
an optical assembly configured to guide the illumination and the imaging light along a beam path between the light source and the image field via a field plane and via a pupil plane,
wherein:
the light source and/or a chromatic filter are downstream of the light source in the beam path;
the light source and/or the chromatic filter are configured to specify a wavelength bandwidth for the imaging light;
the wavelength bandwidth is between a total wavelength bandwidth and a reduction wavelength bandwidth;
the reduction wavelength bandwidth is at least 10% less than the total wavelength bandwidth; and
the chromatic filter and/or the light source are/is overall in a region of the pupil plane.

2. The optical system of claim 1, wherein the chromatic filter is configured to reduce the total wavelength bandwidth of the illumination and imaging light upstream of the chromatic filter to the reduction wavelength bandwidth, and/or wherein the light source is tunable.

3. The optical system of claim 1, wherein the chromatic filter is in an imaging optical unit of the optical system, and the imaging unit is configured to image the object field into the image field.

4. The optical system of claim 1, wherein the light source comprises an array of wavelength-tunable individual light sources.

5. The optical system of claim 1, wherein the chromatic filter and/or the light source are/is arranged overall in a region of the pupil plane.

6. The optical system of claim 5, wherein the chromatic filter has a chromatic filter effect only in a portion of a pupil of the optical system.

7. The optical system of claim 1, wherein the chromatic filter has a chromatic filter effect only in a portion of the field.

8. The optical system of claim 1, wherein the chromatic filter has a chromatic filter effect only in a portion of an entire cross section of the beam path of the illumination and imaging light, and a remaining portion of the beam path is covered by a compensation filter portion.

9. The optical system of claim 1, wherein the chromatic filter comprises an interference filter.

10. The optical system of claim 1, wherein the chromatic filter comprises a high-pass filter.

11. The optical system of claim 1, further comprising a filter interchange holder in which the chromatic filter is held so that the chromatic filter is displaceable between a used position, in which the chromatic filter is in the beam path, and a neutral position, in which the chromatic filter is outside the beam path.

12. An apparatus, comprising:
an optical system according to claim 1;
a projection lens configured to image the object field into the image field,
wherein the apparatus is a projection exposure apparatus.

13. A method, comprising:
providing a projection exposure apparatus which comprises a light source, an optical system according to claim 1 and a projection lens configured to image the object field into the image field;
providing the object and a wafer;
imaging a structure on the object onto the wafer using the projection exposure apparatus; and
processing the exposed wafer to forming a component,
wherein the component comprises a microstructured or nanostructured component.

14. An optical system configured to guide illumination and imaging light from a light source to an image field in which a substrate is arrangeable, the optical system configured to illuminate an object field in which an object is arrangeable and/or to image the object field into the image field, the optical system comprising:
an optical assembly configured to guide the illumination and the imaging light along a beam path between the light source and the image field via a field plane and via a pupil plane,
wherein:
the light source and/or a chromatic filter are downstream of the light source in the beam path;
the light source and/or the chromatic filter are configured to specify a wavelength bandwidth for the imaging light;
the wavelength bandwidth is between a total wavelength bandwidth and a reduction wavelength bandwidth;
the reduction wavelength bandwidth is at least 10% less than the total wavelength bandwidth; and
the chromatic filter and/or the light source are/is in a region of the field plane.

15. The optical system of claim 14, wherein the chromatic filter is configured to reduce the total wavelength bandwidth of the illumination and imaging light upstream of the chromatic filter to the reduction wavelength bandwidth, and/or wherein the light source is tunable.

16. An apparatus, comprising:
an optical system according to claim 14;
a projection lens configured to image the object field into the image field,
wherein the apparatus is a projection exposure apparatus.

17. A method, comprising:
providing a projection exposure apparatus which comprises a light source, an optical system according to claim 14 and a projection lens configured to image the object field into the image field;
providing the object and a wafer;
imaging a structure on the object onto the wafer using the projection exposure apparatus; and
processing the exposed wafer to forming a component,
wherein the component comprises a microstructured or nanostructured component.

18. An optical system configured to guide illumination and imaging light from a light source to an image field in which a substrate is arrangeable, the optical system configured to illuminate an object field in which an object is arrangeable and/or to image the object field into the image field, the optical system comprising:
an optical assembly configured to guide the illumination and the imaging light along a beam path between the light source and the image field via a field plane and via a pupil plane,
wherein:
the light source and/or a chromatic filter are downstream of the light source in the beam path;
the light source and/or the chromatic filter are configured to specify a wavelength bandwidth for the imaging light;
the wavelength bandwidth is between a total wavelength bandwidth and a reduction wavelength bandwidth;
the reduction wavelength bandwidth is at least 10% less than the total wavelength bandwidth;
the chromatic filter is arranged in an imaging optical unit of the optical system; and
the imaging optical unit is configured to image the object field into the image field.

19. An apparatus, comprising:
an optical system according to claim 18;
a projection lens configured to image the object field into the image field,
wherein the apparatus is a projection exposure apparatus.

20. A method, comprising:
providing a projection exposure apparatus which comprises a light source, an optical system according to claim 18 and a projection lens configured to image the object field into the image field;
providing the object and a wafer;
imaging a structure on the object onto the wafer using the projection exposure apparatus; and
processing the exposed wafer to forming a component,
wherein the component comprises a microstructured or nanostructured component.
